(19) United States
(12) Patent Application Publication
(10) Pub. No.: US 2018/0048044 A1
(43) Pub. Date: Feb. 15, 2018

(54) HIGH-DENSITY STACKED GROUNDED COPLANAR WAVEGUIDES

(71) Applicant: QUALCOMM Incorporated, San Diego, CA (US)

(72) Inventors: Yu-Chin Ou, San Diego, CA (US); Mohammad Ali Tassoudji, San Diego, CA (US); Xiaoyin He, San Diego, CA (US); Vladimir Aparin, San Diego, CA (US)

(21) Appl. No.: 15/791,225

(22) Filed: Oct. 23, 2017

Related U.S. Application Data
(62) Division of application No. 14/864,679, filed on Sep. 24, 2015.

(51) Int. Cl. H01P 3/00; H05K 1/02

(52) U.S. Cl. CPC H01P 3/003; H05K 2201/09618; H05K 1/0219; H05K 2201/09236; H01P 3/006

(57) ABSTRACT

A pair of stacked ground coplanar waveguides (GCPWs) is provided in two consecutive metal layers that are deposited on opposing surfaces of a dielectric layer. A first metal layer on a first side of the dielectric layer forms a first signal trace and an upper ground plane for a first GCPW in the pair. Similarly, a second metal layer on a second surface of the dielectric layer forms a second signal trace and an upper ground plane for a second GCPW in the pair.

### CROSS-REFERENCE TO RELATED APPLICATIONS

This application is a divisional of U.S. application Ser. No. 14/864,679, filed Sep. 24, 2015.

### TECHNICAL FIELD

This application relates to waveguides, and more particularly to a two-layer stacked grounded coplanar waveguides.

### BACKGROUND

It is conventional to use grounded coplanar waveguides (GCPWs) for signal routing in a millimeter wave circuit board for signal frequencies of 28 GHz or higher. An example GCPW 100 is shown in FIG. 1. An upper-most metal layer M1 is patterned to include a signal trace 105 and a surrounding upper ground plane 110. An adjacent metal layer M2 forms a lower ground plane 120. The electrical properties for GCPW 100 depends on a number of factors including the separation between the metal layers M1 and M2, the gaps between signal trace 105 and upper ground plane 110, and the width of signal trace 105 as known in the GCPW arts. Metal layer M1 can support additional signal traces for additional GCPWs (not illustrated) so long as there is no intersection of the resulting signal traces.

As the number of signal traces increases, it becomes increasingly difficult to route all the signal traces onto metal layer M1 such that a stacked GCPW architecture is used, which requires additional metal layers. The metal layers are formed in a substrate such as an organic circuit package substrate that uses a central pre-impregnated (prepreg) layer to provide sufficient rigidity. The inclusion of the prepreg layer complicate the resulting stacking of GCPWs. For example, a conventional substrate 200 is shown in FIG. 2 that includes a prepreg layer 230. An upper core (dielectric layer) 226 lies between an upper-most metal layer M1 and a lower metal layer M2. A lower core (dielectric layer) 227 lies between an lower-most metal layer M4 and an adjacent metal layer M3. Each core and its corresponding metal layers are separately patterned to form a corresponding GCPW. For example, metal layer M1 on upper core 226 may be patterned into a signal trace 210 and an upper ground plane 215 for an upper GCPW 211. Metal layer M2 forms a lower ground plane 220 for GCPW 211. Similarly, metal layer M4 may be patterned into a signal trace 235 and an upper ground plane 240 for a GCPW 205. Metal layer M3 forms a lower ground plane 245 for GCPW 205.

After formation of cores 226 and 227 and their corresponding metal layers M1 through M4, the completed cores may then be laminated onto either side of prepeg layer 230. A ground source (not illustrated) may then be coupled to ground plane 215 to provide the desired ground to GCPW 211. Core 226 may include a plurality of vias 225 to couple ground to lower ground plane 220. It would be convenient to use a plurality of vias 250 to couple the same ground source to ground planes 245 and 240 for GCPW 205. But vias 250 are not allowed through prepreg layer 230 due to the lamination of cores 226 and 227 as discussed above.

An realizable construction of a conventional GCPW stack may be better appreciated through a consideration of GCPW stack 300 shown in FIG. 3. An upper core 301 is configured with a metal layer M1 and a second metal layer M2. Metal layer M1 is patterned into a signal trace 315 and an upper ground plane 320 for a first GCPW 305. Metal layer M2 forms a lower ground plane 325 for first GCPW 305. Vias 340 through upper core 301 couple ground planes 320 and 325 together. Similarly, a lower core 302 and its metal layers M3 and M4 are configured to form a second GCPW 301. In particular, metal layer M4 is patterned to form a signal trace 330 and an upper ground plane 335 for second GCPW 310. Metal layer M3 forms a lower ground plane 350 for second GCPW 310. A set of vias 345 extending through lower core 302 couple ground planes 335 and 350 together. The completed cores 302 and 301 may then be laminated onto prepreg layer 230. But note that a ground source (not illustrated) would then be needed to couple to ground plane 320 to provide ground to first GCPW 305 while a second ground source (not illustrated) would be needed to couple to ground plane 335 to provide ground to second GCPW 310. Such a coupling to ground from both sides of GCPW stack 300 is awkward. Since vias from M2 to M4 or from M3 to M1 are not allowed or very impractical due to the lamination onto prepreg layer 230, a laser or mechanical drill may thus be used to form a through-hole via (not illustrated) through ground planes 320, 325, 350, and 335 that may then be plated to couple ground planes 320, 325, 350, and 335 to a common ground. Since this ground via must penetrate through all four metal layers, it must be relatively thick, which lowers density. In addition, note that all four metal layers are used to form GCPW stack 300. The routing of additional signals besides those propagated by GCPWs 305 and 310 is thus hindered by the occupation of all four metal layers by GCPW stack 300.

Accordingly, there is a need in the art for stacked GCPWs with improved density and enhanced signal routing.

### SUMMARY

A pair of stacked ground coplanar waveguides (GCPWs) is provided in two consecutive metal layers that are deposited on opposing surfaces of a dielectric layer. A first metal layer on a first side of the dielectric layer forms a first signal trace and an upper ground plane for a first GCPW in the pair. Similarly, a second metal layer on a second surface of the dielectric layer forms a second signal trace and an upper ground plane for a second GCPW in the pair. The upper ground plane for the first GCPW also functions as the lower ground plane for the second GCPW. Similarly, the upper ground plane for the second GCPW also functions as the lower ground plane for the first GCPW.

The resulting combination of the dielectric layer and the patterned first and second metal layers is readily laminated onto, for example, a pre-impregnated layer to form a millimeter wave circuit board for millimeter wave applications. The resulting millimeter wave circuit board advantageously offers enhanced signal routing in that just two consecutive metal layers are used to form the pair of stacked GCPWs. Additional metal layers in the millimeter wave circuit board may thus be dedicated to other purposes. Moreover, a ground connection to the upper ground plane for the first GCPW may be readily coupled through a plurality of vias extending through the dielectric layer to also ground the upper ground plane for the second GCPW. In this fashion, the grounding of the stacked GCPWs does not require any through-hole vias through the pre-impregnated layer, which enhances density.

These and other advantageous features may be better appreciated through the following detailed description.

### BRIEF DESCRIPTION OF THE DRAWINGS

FIG. 1 is cross-sectional view of a conventional grounded coplanar waveguide (GCPW).

FIG. 2 is a cross-sectional view of a conventional pair of stacked GCPWs in a four-metal-layer substrate with a central pre-impregnated layer highlighted to show a forbidden via formation through the pre-impregnated layer.

FIG. 3 is a cross-sectional view of a conventional pair of stacked GPCWs in a four-metal-layer substrate with a central pre-impregnated layer without any forbidden vias.

FIG. 4 is a cross-sectional view of a pair of stacked GCPWs formed using two consecutive metal layers in a substrate including a central pre-impregnated layer, wherein the GCPWs in the stack are configured such that their corresponding signals are substantially de-coupled in accordance with an aspect of the disclosure.

FIG. 5 is a cross-sectional and perspective view of a pair of stacked GCPWs formed using two metal layers in a substrate having a central pre-impregnated layer, wherein the GCPWs in the stack are configured such that their corresponding signals are substantially coupled in accordance with an aspect of the disclosure.

FIG. 6 is a partially cutaway plan view of a pair of stacked GCPWs formed using two consecutive metal layers in which the signal trace for a first GCPW in the stack longitudinally extends at a right angle to a longitudinal axis for a signal trace in a second GCPW in the stack.

FIG. 7 is a perspective view of a circuit board including a pair of stacked GCPWs formed using two consecutive metal layers coupled to a radio frequency integrated circuit (RFIC) and a patch antenna in accordance with an aspect of the disclosure.

FIG. 8 is a flowchart for a method of coupling a first signal propagating in a first GCPW formed in consecutive two-metal-layer stack with a second signal propagating in a second GCPW formed in the consecutive two-metal-layer stack in accordance with an aspect of the disclosure.

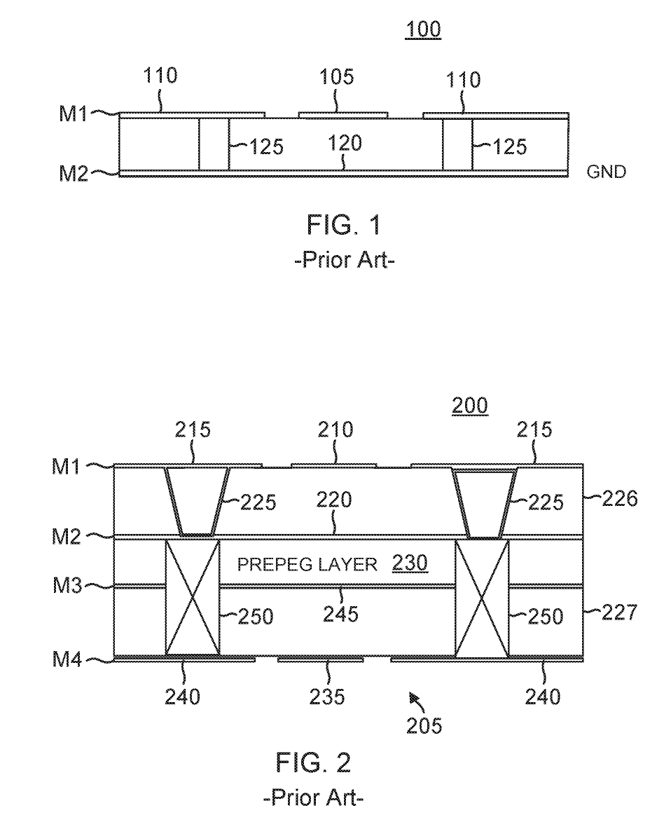

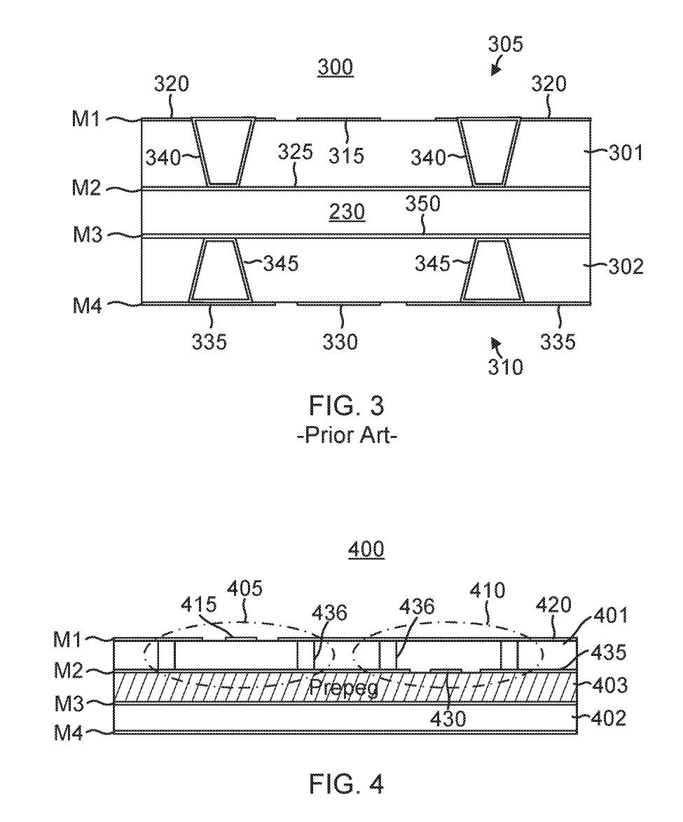

Implementations of the present disclosure and their advantages are best understood by referring to the detailed description that follows. It should be appreciated that like reference numerals are used to identify like elements illustrated in one or more of the figures.

### DETAILED DESCRIPTION

Two consecutive metal layers are configured to form two or more stacked grounded coplanar waveguides (GCPWs) to increase density and provide improved signal routing. As used herein, two metal layers are deemed to be consecutive if no other metal layers intervene between the two metal layers. A first one of the metal layers is patterned to form a signal trace and an upper ground plane for a first GCPW. The upper ground plane for the first GCPW also functions as a lower ground plane for a second GCPW. The remaining second metal layer is patterned to form a signal trace for the second GCPW and an upper ground plane for the second GCPW. The upper ground plane for the second GCPW also functions as the lower ground plane for the first GCPW. In that regard, note that “upper” and “lower” with respect to ground planes are defined herein with regard to a particular GCPW. What is an upper ground plane from one GCPW in a stack formed in two consecutive metal layers is the lower ground plane for the remaining GCPW in the stack.

An example GCPW stack 400 is shown in FIG. 4. The two consecutive metal layers are an upper-most metal layer M1 and an adjacent metal layer M2 that sandwich an upper core dielectric layer 401. Metal layer M1 is patterned such as through photolithography or other suitable techniques to form a signal trace 415 and to form an upper ground plane 420 for a first GCPW 405. Upper ground plane 420 also forms the lower ground plane for a second GCPW 410. Metal layer M2 is patterned such as through photolithography or other suitable techniques to form a signal trace 430 for second GCPW 410 and to form an upper ground plane 435 for second GCPW 410. Upper ground plane 435 also forms a lower ground plane for first GCPW 405. A plurality of vias 436 couple from ground plane 420 to ground plane 435 on either side of signal trace 415 in first GCPW 405. Similarly, a plurality of vias 436 couple from ground plane 420 to ground plane 435 on either side of signal trace 430. Although FIG. 4 is a cross-sectional view, note that signal traces 415 and 430 are extending longitudinally in the same direction. Signal trace 415 thus does not cross over signal trace 430. Similarly, signal trace 430 does not cross under signal trace 415. Vias 436 on a first side of signal trace 415 in GCPW 405 are arranged in a series that extends longitudinally with signal trace 415 to form a “via wall” as will be further explained herein. Similarly, vias 436 on a remaining second side of signal trace 415 in GCPW 405 are arranged in a similar via wall. Signal vias 436 on either side of signal trace 430 in GCPW 410 are arranged into a similar pair of via walls that sandwich signal trace 430. The resulting grounded via walls form a very strong isolation between a signal propagated through GCPW 405 and any signal propagated (or not) through GCPW 410 since signal trace 415 does not cross over signal trace 430. This isolation is reciprocal in that should there be a signal propagated through GCPW 410, it too will be strongly isolated from coupling into GCPW 405. In one implementation, vias 436 may be deemed to comprise means for coupling upper ground plane 420 for the first GCPW 405 to an upper ground plane 436 for the second GCPW 410.

The resulting patterned core layer 401 and its GCPWs 405 and 410 may be laminated onto a first surface of prepreg layer 403. Metal layer M2 is thus fused or adhered onto the first surface of prepreg layer 403. At the same time or in a separate manufacturing step, another dielectric core layer 402 and its metal layers M3 and M4 may be similarly laminated onto an opposing second surface of prepreg layer 403 such that metal layer M3 fuses or adheres to the second surface of prepreg layer 403. Note that metal layers M3 and M4 may be patterned (not illustrated) to support other signals independently from the routing of signals through GCPWs 405 and 410. In this fashion, signal routing flexibility is enhanced. In addition, no through-hole via is necessary to ground metal layers M1, M2, M3, and M4 together since one or more ground contacts (not illustrated) coupled to ground plane 420 is sufficient to provide ground to both GCPWs 405 and 410.

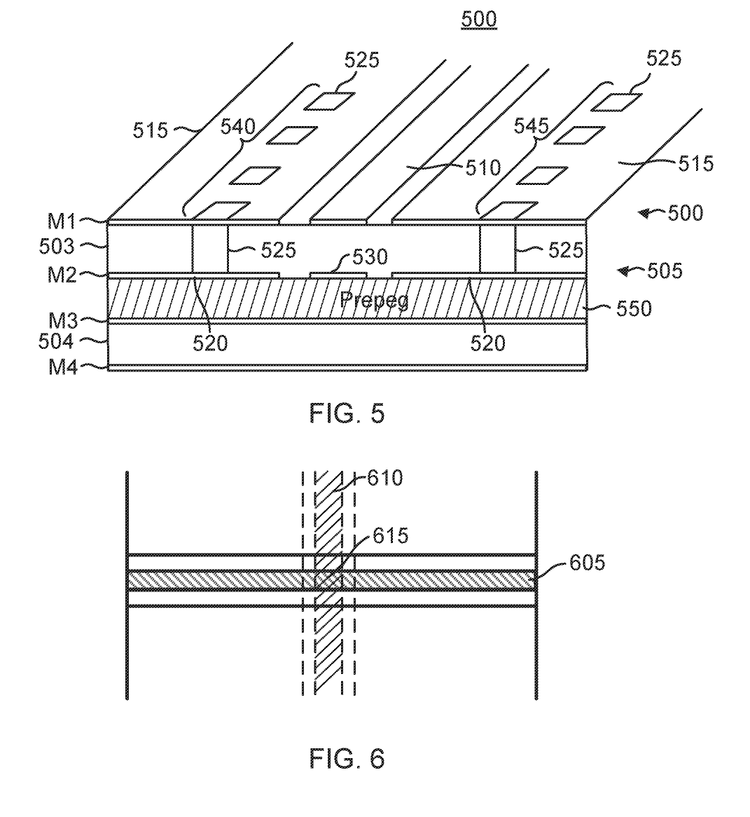

In an alternative implementation, a GCPW stack 500 as shown in FIG. 5 is configured such that a signal propagating through a first GCPW 501 will strongly couple into a second GCPW 505. This coupling may be reciprocal such that a signal propagating through GCPW 505 will also strongly couple into GCPW 501. GCPWs 501 and 505 are formed in a first metal layer M1 and a consecutive metal layer M2 that sandwich a core dielectric layer 503. Metal layer M1 is patterned to form a signal trace 510 and an upper ground plane 515 for GCPW 501. Upper ground plane 515 also functions as a lower ground plane for GCPW 505. Metal layer M2 is patterned to form a signal trace 530 and an upper ground plane 520 for GCPW 505. Upper ground plane 520 for GCPW 505 also functions as the lower ground plane for GCPW 501.

In contrast to GCPW stack 400 of FIG. 4, signal trace 510 of GCPW 501 overlays signal trace 530. Both signal traces 510 and 530 extend longitudinally in the same direction such that signal trace 510 completely overlays signal trace 530 along its entire longitudinal extent. Given this complete overlay of signal trace 510 onto signal trace 530, a plurality of vias 525 extending through core layer 503 from ground plane 515 to ground plane 520 form a pair of vias walls that are shared by both GCPWs 501 and 505. In particular, a first set of vias 525 form a first via wall 540 on a first side of signal traces 510 and 530. A second set of vias 525 form a second via wall 545 on an opposing second side of signal traces 510 and 530. There are thus no via walls in GCPW stack 500 that isolate GCPW 501 from GCPW 505. This lack of isolation and the overlay of signal trace 510 over signal trace 530 causes a signal propagated through GCPW 501 to couple relatively strongly into GCPW 505. Similarly, a signal propagated through GCPW 505 will strongly couple into GCPW 501.

Core 503 with its vias 525 and its patterned metal layers M1 and M2 may then be laminated onto a first surface of a prepreg layer 550. Another core layer 504 sandwiched by metal layers M3 and M4 may also be laminated onto an opposing second surface of prepreg layer 550. Prior to this lamination, metal layers M3 and M4 may be patterned as desired to carry signals besides those propagated through GCPWs 501 and 505. In addition, a ground contact (not illustrated) may supply ground to GCPWs 501 and 505 through a contact to first upper ground plane 515 without the need for any through-hole vias through prepreg layer 550.

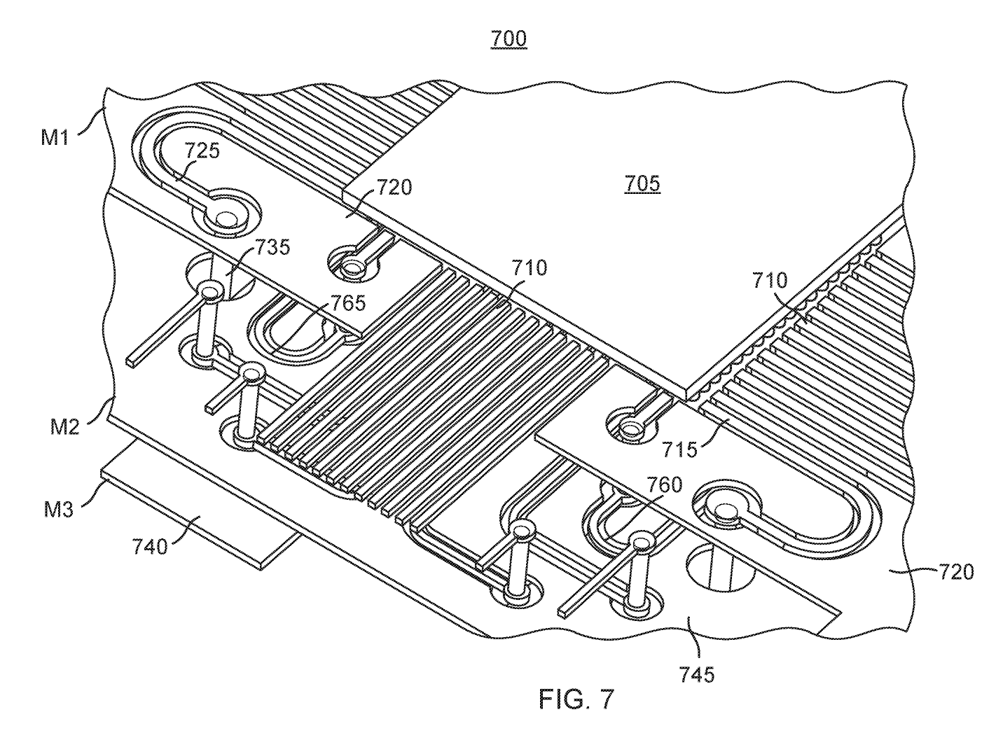

GCPW stacks 400 and 500 of FIGS. 4 and 5 represent two extremes: relatively strong isolation between GCPWs 405 and 410 in stack 400 versus relatively little isolation between GCPWs 501 and 505 in stack 500. In stack 400, signal trace 415 never overlays signal trace 430 so that the resulting via walls formed by vias 436 provide strong isolation between GCPWs 405 and 410. Conversely, signal trace 510 completely overlays signal trace 530 so that vias walls 540 and 545 are shared and provide relatively little isolation. Given these two extremes, a moderate amount of coupling from one GCPW to another in a stack may be accomplished by varying the degree of overlay. For example, a signal trace 605 for an upper GCPW shown in FIG. 6 crosses a signal trace 610 for an underlying GCPW at a 90 degree angle. In contrast, the overlay for signal trace 510 onto signal trace 530 in stack 500 may be deemed to be a zero degree overlay. The 90 degree crossing for signal trace 605 over signal trace 610 thus presents a reduced cross-over area 615 in which signal trace 605 overlays signal trace 610. By varying the angle at which one signal trace overlays another in a pair of stacked GCPWs, a circuit designer may vary the coupling between the upper and lower GCPWs in the stack accordingly. With regard to signal trace 605, the 90 degree crossing over signal trace 610 produces a moderate amount of coupling that would have a magnitude in between the extremes of GCPW stacks 400 and 500. If the longitudinal axis of signal trace 605 were made to be more and more parallel to the longitudinal axis of signal trace 610 while signal trace 605 continues to overlay signal trace 610, cross-over area 615 would continue to grow so as to produce more and more signal coupling. At the extreme of a zero degree crossing angle, cross-over area 615 becomes identical to the surface area of either signal trace 610 and 605 (assuming they have the same widths). By thus varying the cross-over area of one signal trace over another in a GCPW stack, a circuit designer may provide a desired amount of signal coupling between the corresponding GCPWs. For example, a bandpass filter may require a certain amount of coupling between GCPWs whereas a built-in-self test (BIST) may require another amount of coupling. In that regard, the formation of a pair of stacked GCPWs into two consecutive metal layers as disclosed herein provides a compact and convenient structure for BIST operation. During a BIST mode, a BIST signal may be driven into one of the GPCPWs in the stack. Depending upon the cross-over area, the BIST signal will then couple into the remaining GCPW in the stack so that it may be used to confirm desired functionality of the tested system.

The GCPW stacks in two consecutive metal layers as disclosed herein may be advantageously applied in a millimeter-wave circuit board including an RFIC. For example, a millimeter-wave circuit board 700 shown in FIG. 7 includes an RFIC 705 mounted on an upper-most metal layer M1. Metal layer M1 may be patterned into a plurality of conventional traces 710 through which RFIC 705 may drive a corresponding plurality of digital signals. In addition, metal layer M1 may be patterned to form a signal trace 725 and an upper ground plane for an upper GCPW in a stack that includes a signal trace 765 patterned into metal layer M2 for a lower GCPW. A lower ground plane 745 formed in metal layer M2 for the upper GCPW having signal trace 765 also functions as the upper ground plane for the lower GCPW including signal trace 765. In this configuration, signal trace 725 crosses signal trace 765 at a right angle to introduce a limited amount of coupling between signal traces 725 and 765. Signal trace 725 couples to a through-hole via 735 that extends through metal layer M2 to a patch antenna 740 formed in a bottom-most metal layer M3. A prepreg layer (not illustrated) may intervene between metal layers M2 and M3 such that circuit board 700 includes three metal layers. Rather than use a via 735 to drive patch antenna 740, signal trace 725 could also indirectly couple to patch antenna 740 through an aperture (not illustrated) in metal layer M2. A fourth metal layer (or even additional metal layers) may be included in circuit board 700 in an alternative implementations. Another GCPW signal trace 715 in metal layer M1 may cross over another GCPW signal trace 760 in metal layer M2 at right angles to again introduce a limited amount of coupling between the signals propagated in traces 715 and 760.

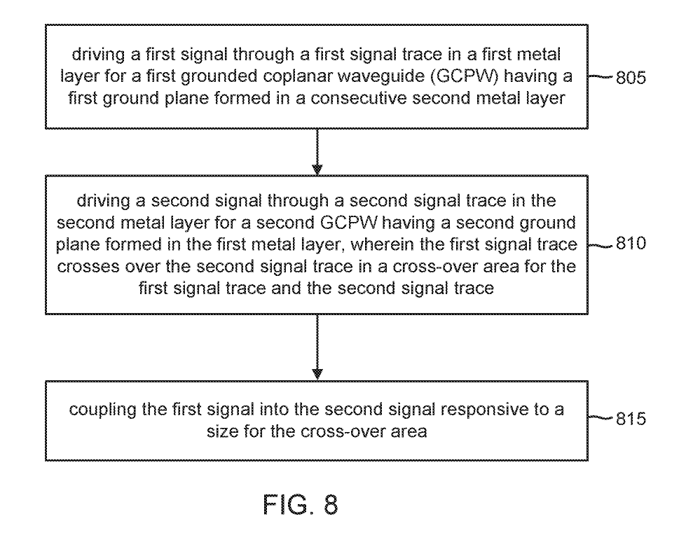

A method of operating a GCPW stack formed in two consecutive metal layers in accordance with an aspect of the disclosure will now be discussed with regard to the flowchart of FIG. 8. The method includes an act 800 of driving a first signal through a first signal trace in a first metal layer for a grounded coplanar waveguide (GCPW) having a first ground plane formed in a consecutive second metal layer. An example of act 800 comprises driving a signal through signal trace 510 of GCPW stack 500 in FIG. 5 or through signal trace 605 of FIG. 6. The method also includes an act 805 of driving a second signal through a second signal trace in the second metal layer for a second GCPW having a second ground plane formed in the first metal layer, wherein the first signal trace crosses over the second signal trace in a cross-over area for the first signal trace and the second signal trace. An example of act 805 comprises driving a signal into signal trace 530 of FIG. 5 or into signal trace 610 of FIG. 6. Finally, the method includes an act 810 of coupling the first signal into the second signal responsive to a size for the cross-over area. The large cross-over area for GCPW stack 500 that leads to a large signal coupling as well as the reduced cross-over area 615 of FIG. 6 that leads to a reduced signal coupling are examples of act 810.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

We claim:

1. A stacked waveguide, comprising:
a first dielectric layer having a first surface and an opposing second surface;
a first metal layer on the first surface of the first dielectric layer, wherein the first metal layer is configured to form both a first signal trace and a first upper ground plane for a first grounded coplanar waveguide (GCPW); and
a second metal layer on the second surface of the first dielectric layer, wherein the second metal layer is configured to form both a second signal trace and a second upper ground plane for a second GCPW, and wherein the second upper ground plane for the second GCPW is further configured to form a first lower ground plane for the first GCPW, and wherein the first upper ground plane is further configured to form a second lower ground plane for the second GCPW, and wherein the first signal trace is arranged to cross over the second signal trace.

2. The stacked waveguide of claim 1, wherein the first signal trace is further arranged to cross over the second signal trace at a right angle.

3. The stacked waveguide of claim 1, wherein the first signal trace is further arranged to completely overlay the second signal trace such that the first signal trace has a zero degree angle of cross-over with regard to the second signal trace.

4. The stacked waveguide of claim 1, further comprising a plurality of vias extending through the first dielectric layer to couple the first upper ground plane to the first lower ground plane and to couple the second upper ground plane to the second lower ground plane.

5. The stacked waveguide of claim 4, further comprising a plurality of vias extending through the first dielectric layer to couple the first upper ground plane to the first lower ground plane and to couple the second upper ground plane to the second lower ground plane, wherein a first subset of the vias are arranged into a series to form a first via wall adjacent a first side of the first signal trace, and wherein a second subset of the vias are arranged into a series to form a second via wall adjacent a second side of the first signal trace.

6. The stacked waveguide of claim 5, wherein a third subset of the vias are arranged into a series to form a third via wall between a first side of the second signal trace and the second via wall, and wherein a fourth subset of the vias are arranged into a series to form a fourth via wall adjacent a second side of the second signal trace.

7. The stacked waveguide of claim 1, further comprising a radio-frequency integrated circuit (RFIC) configured to drive a first RF signal into the first signal trace.

8. The stacked waveguide of claim 7, wherein the RFIC is further configured to drive a built-in-self-test (BIST) signal into the second signal trace.

9. The stacked waveguide of claim 1, further comprising a pre-impregnated (prepreg) layer attached to the second metal layer.

10. The stacked waveguide of claim 9, further comprising:
a second dielectric layer having a first surface and an opposing second surface;
a third metal layer attached to the first surface of the second dielectric layer; and
a fourth metal layer attached to the second surface of the second dielectric layer, wherein the third metal layer is also attached to the prepreg layer.

11. A method of operating a stacked waveguide, comprising:
driving a first signal through a first signal trace in a first metal layer for a first grounded coplanar waveguide (GCPW) having a first ground plane formed in a consecutive second metal layer;
driving a second signal through a second signal trace in the second metal layer for a second GCPW having a second ground plane formed in the first metal layer, wherein the first signal trace crosses over the second signal trace in a cross-over area for the first signal trace and the second signal trace; and
coupling the first signal into the second signal responsive to a size for the cross-over area.

12. The method of claim 11, wherein the coupling the first signal into the second signal comprises coupling a built-in-self-test (BIST) signal into the second signal.

13. The method of claim 11, wherein the coupling the first signal into the second signal comprises filtering the first signal.

14. The method of claim 11, wherein driving the first signal into the first signal trace comprises driving a signal having a frequency of greater than 28 GHz into the first signal trace.
